(19) United States
(12) Patent Application Publication
(10) Pub. No.: US 2024/0249963 A1
(43) Pub. Date: Jul. 25, 2024

(54) SUBSTRATE PROCESSING APPARATUS, TRANSFER METHOD OF SUBSTRATE SUPPORT, RECORDING MEDIUM, AND MANUFACTURING METHOD OF SEMICONDUCTOR DEVICE

(71) Applicant: Kokusai Electric Corporation, Tokyo (JP)

(72) Inventors: Yukinori ABURATANI, Toyama-shi (JP); Naofumi Ohashi, Toyama-shi (JP)

(73) Assignee: Kokusai Electric Corporation, Tokyo (JP)

(21) Appl. No.: 18/421,051

(22) Filed: Jan. 24, 2024

(30) Foreign Application Priority Data
Jan. 25, 2023 (JP) 2023-009603

(51) Int. Cl. H01L 21/673; H01L 21/677

(52) U.S. Cl. CPC H01L 21/67309; H01L 21/67306; H01L 21/67745; H01L 21/67757; H01L 21/67769

(57) ABSTRACT

There is provided a technique that includes a process chamber in which a substrate is processed; a plurality of substrate supports configured to support the substrate; a rotatable table including a plurality of supports configured to support the plurality of substrate supports; and a heat conduction insulator configured to suppress heat conduction between the plurality of supports.

### CROSS-REFERENCE TO RELATED APPLICATION

This application is based upon and claims the benefit of priority from Japanese Patent Application No. 2023-009603, filed on Jan. 25, 2023, the entire contents of which are incorporated herein by reference.

### TECHNICAL FIELD

The present disclosure relates to a substrate processing apparatus, a transfer method of a substrate support, a recording medium, and a manufacturing method of a semiconductor device.

### BACKGROUND

As one semiconductor device manufacturing step, there may be a step where a substrate support that supports a substrate thereon is loaded into a process furnace of a substrate processing apparatus, allowing for substrate processing. As described above, when processing the substrate inside the process furnace, the substrate becomes a high temperature immediately after the processing. Therefore, there is a need to wait for the substrate to cool down, which may lead to a decrease in throughput.

### SUMMARY

Some embodiments of the present disclosure provide a technique that allows for improving throughput while reducing susceptibility to the effects of heat.

According to one embodiment of the present disclosure, there is provided a technique that includes a process chamber in which a substrate is processed; a plurality of substrate supports configured to support the substrate; a rotatable table including a plurality of supports configured to support the plurality of substrate supports; and a heat conduction insulator configured to suppress heat conduction between the plurality of supports.

### BRIEF DESCRIPTION OF DRAWINGS

The accompanying drawings, which are incorporated in and constitute a part of the specification, illustrate one or more embodiments of the present disclosure.

FIG. 1 is a plan cross-sectional view of a substrate processing apparatus according to one embodiment of the present disclosure.

FIG. 2 is a side cross-sectional view of the substrate processing apparatus according to one embodiment of the present disclosure.

FIG. 3 is a diagram illustrating an example of a substrate support according to one embodiment of the present disclosure.

FIG. 4 is a block diagram of a schematic configuration of a controller in the substrate processing apparatus according to one embodiment of the present disclosure and illustrates a control system of the controller.

FIG. 5 is a diagram illustrating a modification of a rotatable table in a substrate processing apparatus according to another embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### One Embodiment of This Disclosure

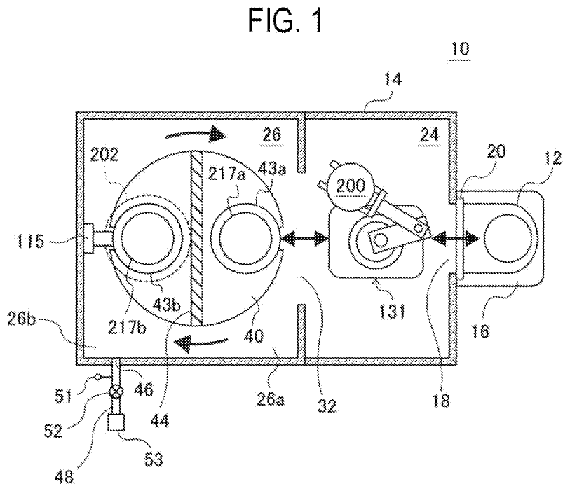

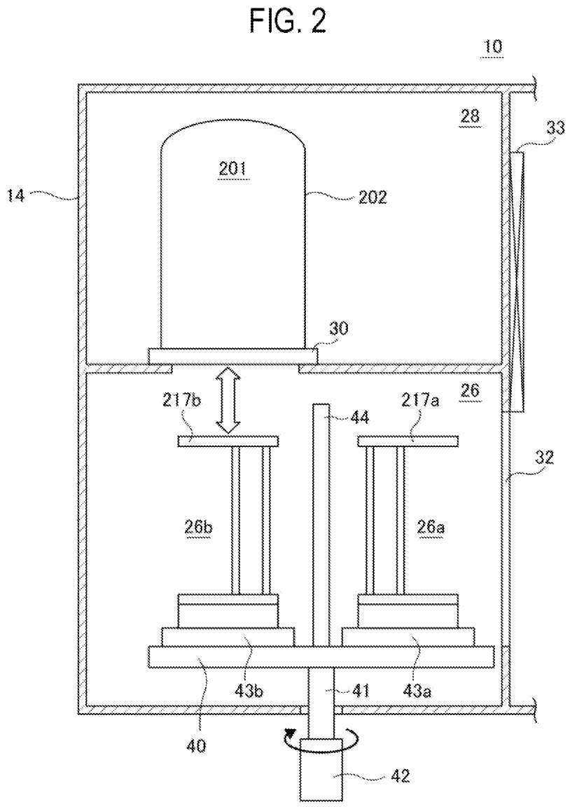

Hereinafter, one embodiment of the present disclosure will be described mainly with reference to FIGS. 1 to 4. In addition, the drawings used in the following description are all schematic, and the dimensional relationship of each element, the ratio of each element, and the like illustrated in the drawings do not essentially match with those in reality. Further, the dimensional relationship of each element, the ratio of each element, and the like do not essentially match between multiple drawings as well.

### (1) Configuration of Substrate Processing Apparatus

A wafer 200, which serves as a substrate to be processed by a substrate processing apparatus 10, is accommodated in a predetermined number inside a pod 12, which serves as a sealed substrate transfer container, and is then loaded into and unloaded from the substrate processing apparatus 10.

The substrate processing apparatus 10 includes a housing 14, and a front wall of the housing 14 is provided with a substrate loading port 18 adjacent to a pod stage 16. A pod opener 20 is provided at the substrate loading port 18, a lid of the pod opener 20 is opened and closed by the pod opener 20, and the wafer 200 is loaded and unloaded through the substrate loading port 18.

The interior of the housing 14 is partitioned into a transfer area 24, a load lock chamber 26 adjacent to the rear of the transfer area 24, and a processing area 28 adjacent to the top of the load lock chamber 26, in which a process furnace 202 is arranged.

In other words, the load lock chamber 26 is positioned in the inner rear region of the housing 14, and the process furnace 202 is consecutively positioned above the load lock chamber 26. A furnace opening formed at a lower end of the process furnace 202 is openable/closeable by a furnace opening shutter 30.

A substrate carrier 131 is arranged in the transfer area 24 between the pod stage 16 and the load lock chamber 26. The substrate carrier 131 is capable of holding a predetermined number of, for example, five wafers 200 to load and unload them into a boat 217a or boat 217b, which serves as a substrate support, through a front side opening 32 of the load lock chamber 26. In other words, the substrate carrier 131 allows for the transfer of the wafers 200 between the pod 12 on the pod stage 16 and at least one of the boat 217a or boat 217b in a first area 26a to be described later.

The front side opening 32 is opened and closed by a gate valve 33, and is airtightly sealed in the closed state thereof.

The load lock chamber 26 is mainly provided with a rotatable table 40, the boats 217a and 217b, and a boat elevator 115 serving as a transfer mechanism.

The rotatable table 40 has, for example, a disk shape. A rotating shaft 41 is provided at approximately the center of a lower surface of the rotatable table 40. The rotating shaft 41 is connected to a rotatable table rotator 42 that rotates the rotatable table 40. Further, supports 43a and 43b, which support the boats 217a and 217b respectively, are provided on an upper surface of the rotatable table 40. In other words, two boats 217a and 217b are rotatably disposed on the rotatable table 40.

An isolator 44, which serves as a heat conduction insulator, is provided substantially perpendicular to the upper surface of the rotatable table 40 between the support 43a and the support 43b of the rotatable table 40. The isolator 44 is formed into a plate shape. Further, the isolator 44 has a structure having a vacuum thermal-insulation effect. Here, “having a vacuum thermal-insulation effect” means that the isolator 44 is not only made of a vacuum thermal-insulation material, which is a thermal insulation material with the interior maintained in a vacuum state, but also made of a material having an effect equivalent to the vacuum thermal-insulation material.

Further, the isolator 44 is configured such that an upper end of the isolator 44 is positioned higher than upper end surfaces of the boats 217a and 217b in a state where the boats 217a and 217b are supported on the supports 43a and 43b, respectively. The isolator 44 is configured to suppress, between the supports 43a and 43b, heat conduction between the boat 217a supported on the support 43a and the boat 217b supported on the support 43b, and to thermally isolate the boats 217a and the boat 217b from each other.

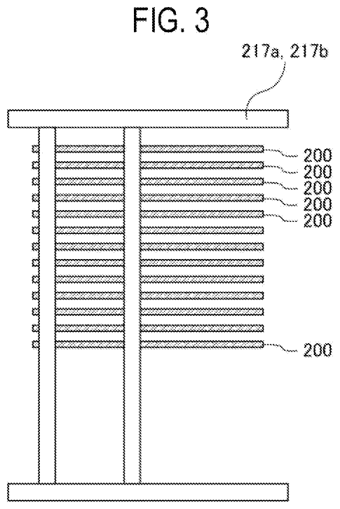

The boats 217a and 217b are configured to support a plurality of wafers 200 with a horizontal posture in multiple stages, for example, as illustrated in FIG. 3. The isolator 44 may be configured to thermally isolate at least the area where the wafers 200 are mounted in the boats 217a and 217b.

A process chamber 201 inside the process furnace 202 is arranged above the rotatable table 40 and above a second area 26b to be described later.

The interior of the load lock chamber 26 above the rotatable table 40 includes the first area 26a where the wafer 200 is transferred between the boat 217a or boat 217b and the pod 12, and includes the second area 26b where the boat 217a or boat 217b is transferred between the rotatable table 40 and the process chamber 201 above the rotatable table 40. The first area 26a and the second area 26b above the rotatable table 40 are isolated by the isolator 44. In other words, the first area 26a and the second area 26b are thermally isolated, and heat conduction is suppressed.

The boat elevator 115 is arranged in the second area 26b. The boat elevator 115 is configured to transfer the boat 217a or boat 217b, supported on the support 43a or support 43b, between the process chamber 201 inside the process furnace 202 and the rotatable table 40 by supporting the support 43a or support 43b.

The supports 43a and 43b are used respectively as seals that airtightly seal the furnace opening of the process furnace 202.

The boat 217a or boat 217b arranged in the second area 26b is configured to be raised and lowered by the boat elevator 115 and to be loaded into and unloaded from the process furnace 202.

An exhaust port 46 for exhausting the atmosphere inside the load lock chamber 26 is provided at the housing 14 constituting the load lock chamber 26. An exhaust pipe 48 is connected to the exhaust port 46. The exhaust pipe 48 is connected to a vacuum pump 53, which serves as a vacuum-exhaust device, via a pressure sensor 51 as a pressure detector that detects the internal pressure of the housing 14 and an auto pressure controller (APC) valve 52 as a pressure regulator. The APC valve 52 is configured to be opened and closed during the operation of the vacuum pump 53, thereby being capable of initiating or stopping the vacuum-exhaust of the load lock chamber 26. The opening degree of the APC valve 52 may be regulated based on pressure information detected by the pressure sensor 51 during the operation of vacuum pump 53, which allows for regulating the internal pressure of the load lock chamber 26. An exhaust system is mainly includes the exhaust pipe 48, APC valve 52, and pressure sensor 51. The vacuum pump 53 may be included in the exhaust system.

### (2) Configuration of Controller

Next, a configuration of a controller 121, which serves as a control part (control means), will be described.

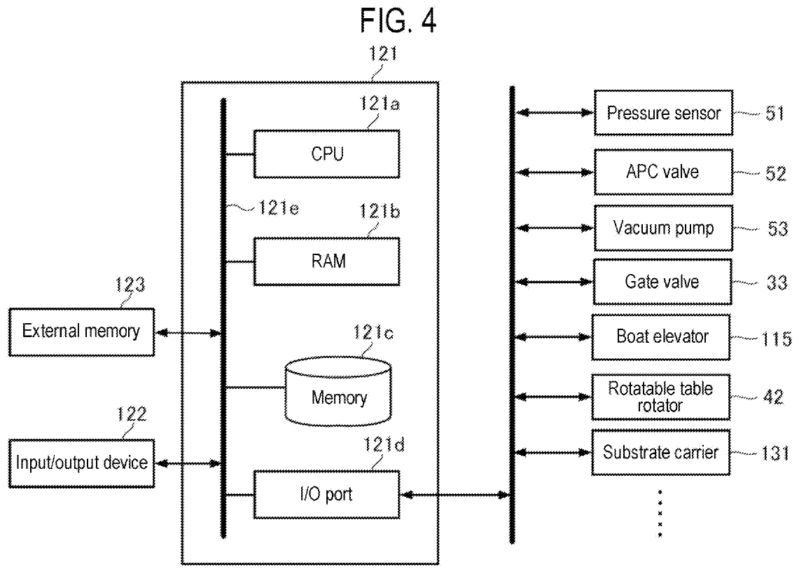

As illustrated in FIG. 4, the controller 121 is configured as a computer including a central processing unit (CPU) 121a, a random access memory (RAM) 121b, a memory 121c, and an I/O port 121d. The RAM 121b, memory 121c, and I/O port 121d are configured to be data-exchangeable with the CPU 121a via an internal bus 121e. An input/output device 122, which is configured as, for example, a touch panel, etc., is connected to the controller 121.

The memory 121c includes, for example, a flash memory, a hard disk drive (HDD), and others. The memory 121c stores, in a readable manner, a control program for controlling the operation of the substrate processing apparatus 10, a process recipe containing procedures, conditions and others of a substrate processing step to be described later, and others. In addition, the process recipe is a combination of respective procedures of a substrate processing step to be described later, which are executed by the controller 121 to achieve predetermined results, and thus, functions as a program. Hereinafter, the process recipe, control program, and others are collectively referred to simply as “program”. In addition, when the term “program” is used in this specification, it may refer to only the process recipe, only the control program, or both. Further, the RAM 121b is configured as a memory area (work area) where programs, data, and others read by the CPU 121a are temporarily held.

The I/O port 121d is connected to various components described above, including the pressure sensor 51, the APC valve 52, the vacuum pump 53, the gate valve 33, the boat elevator 115, the rotatable table rotator 42, and the substrate carrier 131.

The CPU 121a is configured not only to read and execute the control program from the memory 121c but also to read the process recipe from the memory 121c in response to the input of an operation command from the input/output device 122. Then, the CPU 121a is configured to control various operations, including the vacuum-exhaust of the load lock chamber 26 by the pressure sensor 51, APC valve 52, and vacuum pump 53, the opening and closing of the gate valve 33, the transfer of the wafer 200 by the substrate carrier 131, the rotation of the rotatable table 40 by the rotatable table rotator 42, the vertical movement of the boat 217a or boat 217b by the boat elevator 115, so as to follow the contents of the read process recipe.

In addition, the controller 121 may be configured as a general-purpose computer without being limited to be configured as a dedicated computer. For example, the controller 121 according to this embodiment may be configured by preparing an external memory storing the above-described program (e.g., magnetic tapes, magnetic disks such as flexible disks and hard disks, optical disks such as CDs and DVDs, magneto-optical disks such as MOs, and semiconductor memories such as USB memories (USB flash drives) and memory cards) 123, and installing a program onto a general-purpose computer using the external memory 123. In addition, a way for supplying the program to the computer is not limited to the supply of the program using the external memory 123. For example, the program may be supplied using a communication facility such as the Internet or a dedicated line without the external memory 123. In addition, the memory 121c or the external memory 123 is configured as a computer-readable recording medium. Hereinafter, these are collectively referred to as recording media. In addition, when the term “recording medium” is used in this specification, it may refer to only the memory 121c, only the external memory 123, or both.

### (3) Substrate Processing Step

Next, an overview of substrate processing by the substrate processing apparatus 10 having the above-described configuration will be described as one semiconductor manufacturing step. In addition, in the following description, an operation of each part constituting the substrate processing apparatus 10 is controlled by the controller 121.

The pod 12 is transferred to the pod stage 16.

The substrate loading port 18 and the pod 12 are opened, the front side opening 32 is opened by the gate valve 33, and the wafer 200 is transferred to the boat 217a in the first area 26a by the substrate carrier 131.

If a predefined number of wafers 200 are loaded into the boat 217a in the first area 26a, the boat 217a is transferred to the second area 26b by rotation of the rotatable table 40. Then, the front side opening 32 is closed by the gate valve 33, and the load lock chamber 26 is vacuum-exhausted from the exhaust pipe 48, thereby being depressurized.

If the load lock chamber 26 is depressurized to the same pressure as the internal pressure of the process furnace 202, the furnace opening is opened by the furnace opening shutter 30. Subsequently, the boat 217a on the support 43a is loaded into the process furnace 202 by the boat elevator 115.

After the loading, a predetermined processing is performed on the wafer 200 in the process chamber 201 inside the process furnace 202. At this time, the empty boat 217b is arranged in the first area 26a.

During the processing of the wafer 200 in the boat 217a, the next pod 12 is transferred to the pod stage 16, and in the same procedure as the above-described procedure, the substrate loading port 18 and the pod 12 are opened, the front side opening 32 is opened by the gate valve 33, and the wafer 200 is transferred to the boat 217b in the first area 26a by the substrate carrier 131. Then, the front side opening 32 is closed by the gate valve 33, and the load lock chamber 26 is vacuum-exhausted from the exhaust pipe 48, thereby being depressurized.

After the processing, the boat 217a is pulled onto the rotatable table 40 by the boat elevator 115, and the furnace opening is closed by the furnace opening shutter 30. At this time, over the rotatable table 40, the boat 217a supporting the processed wafer 200 and the boat 217b supporting the unprocessed wafer 200 are supported. In other words, both the processed wafer 200 and the unprocessed wafer 200 are arranged over the rotatable table 40 at the same timing.

Here, since the processed wafer 200 is at a high temperature immediately after the processing, if a gap between the processed wafer 200 and the unprocessed wafer 200 is too narrow, it may lead to the oxidation of the surface of the unprocessed wafer 200 or the growth of crystal grains on the surface of the wafer 200 due to the impact of heat. Further, if the gap between the processed wafer 200 and the unprocessed wafer 200 is too wide, it may result in a larger footprint, potentially leading to an apparatus size increase.

In this embodiment, due to the presence of the isolator 44 between the boats 217a and 217b on the rotatable table 40, even when the gap between the processed wafer 200 and the unprocessed wafer 200 is narrow, it is possible to prevent heat conduction between the second area 26b where the boat 217a is arranged and the first area 26a where the boat 217b is arranged. In other words, it is possible to reduce the footprint and downsize the apparatus while thermally isolating the boats 217a and 217b from each other. Accordingly, it is possible to minimize the impact of heat from the processed wafer 200 on the unprocessed wafer 200.

Then, by rotation of the rotatable table 40, the boat 217a supporting the processed wafer 200 is transferred from the second area 26b to the first area 26a, and the boat 217b supporting the unprocessed wafer 200 is transferred from the first area 26a to the second area 26b. In other words, the positions of the boats 217a and 217b are exchanged by rotating the rotatable table 40 while they are supported on the respective supports 43a and 43b, under a suppressed heat conduction in the respective areas.

Then, the boat 217b is loaded into the process furnace 202 by the boat elevator 115.

After the loading, a predetermined processing is performed on the wafer 200 in the process chamber 201. At this time, if the boat 217a supporting the processed wafer 200 is arranged in the first area 26a and the wafer 200 supported by the boat 217a is cooled, the internal pressure of the load lock chamber 26 is returned to the atmospheric pressure, and then the gate valve 33 is opened. After that, the wafer 200 and the pod 12 are discharged out of the housing 14 in the opposite procedure as described above, and the next wafer 200 is transferred to the boat 217a in the same procedure as described above.

In this way, in the load lock chamber 26, the rotatable table 40 supporting a plurality of boats is provided and during the processing of the wafer 200 in one boat, the unprocessed wafer 200 may be transferred to the other boat. In other words, it is possible to perform both substrate processing and substrate transfer at the same timing, by using a plurality of boats. This may improve the speed of substrate processing, achieving an enhanced throughput. Furthermore, by thermally isolating each boat on the rotatable table 40, the unprocessed wafer is less susceptible to the impact of heat from the boat immediately after the processing. In other words, it is possible to prevent the oxidation of the surface of the unprocessed wafer or the growth of crystal grains on the surface due to the impact of heat.

### Another Embodiment of This Disclosure

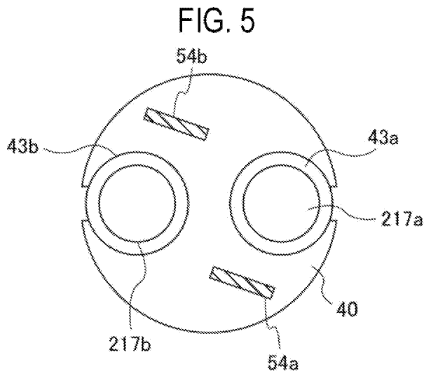

Next, a substrate processing apparatus according to another embodiment of the present disclosure will be described with reference to FIG. 5. In addition, the substrate processing apparatus according to this embodiment is configured, similarly to the apparatus configuration and control configuration illustrated in FIGS. 1 to 4, and the same reference numbers will be given to elements substantially the same as those described in FIGS. 1 to 3 and a description thereof will be omitted. Specifically, this embodiment uses inert gas suppliers 54a and 54b as heat conduction insulators for the rotatable table 40 in the substrate processing apparatus 10 described above.

### (1) Configuration of Rotatable Table

In this embodiment, the inert gas suppliers 54a and 54b are provided as heat conduction insulators that suppress heat conduction between the supports 43a and 43b over the rotatable table 40 and between the boats 217a and 217b. The inert gas suppliers 54a and 54b are provided to supply an inert gas to each of the boats 217a and 217b over the rotatable table 40. The inert gas suppliers 54a and 54b may also be referred to as cooling gas suppliers that supply a cooling gas for cooling the wafer 200 or the boats 217a and 217b.

The inert gas suppliers 54a and 54b are provided at the rotatable table 40 and are configured to rotate together with the boats 217a and 217b. Further, the inert gas suppliers 54a and 54b face the boats 217a and 217b, respectively. Further, the inert gas supplier 54a and the inert gas supplier 54b are point-symmetrically arranged with respect to the rotating shaft 41 of the rotatable table 40. The inert gas suppliers 54a and 54b have a plurality of holes formed in the vertical direction at positions of heights corresponding to the respective wafers 200 supported on the boats 217a and 217b, and are configured to supply the inert gas to the respective wafers 200 from the plurality of holes. In other words, it is possible to thermally isolate the boats 217a and 217b from each other by supplying the inert gas to the boats 217a and 217b from the inert gas suppliers 54a and 54b.

### (2) Substrate Processing Step

Next, an overview of substrate processing by the substrate processing apparatus 10 when using the rotatable table 40 according to another embodiment having the above-described configuration will be described as one semiconductor manufacturing step.

The pod 12 is transferred to the pod stage 16.

The substrate loading port 18 and the pod 12 are opened, the front side opening 32 is opened by the gate valve 33, and the wafer 200 is transferred to the boat 217a in the first area 26a by the substrate carrier 131.

If a predefined number of wafers 200 are loaded into the boat 217a in the first area 26a, the boat 217a is transferred to the second area 26b by rotation of the rotatable table 40. At this time, the supply of inert gas by the inert gas suppliers 54a and 54b is stopped.

If the load lock chamber 26 is depressurized to the same pressure as the internal pressure of the process furnace 202, the furnace opening is opened by the furnace opening shutter 30. Subsequently, the boat 217a is loaded into the process furnace 202 by the boat elevator 115.

After the loading, a predetermined processing is performed on the wafer 200 in the process chamber 202. At this time, the empty boat 217b is arranged in the first area 26a.

During the processing of the wafer 200 in the boat 217a, the next pod 12 is transferred to the pod stage 16, and in the same procedure as the above-described procedure, the substrate loading port 18 and the pod 12 are opened, the front side opening 32 is opened by the gate valve 33, and the wafer 200 is transferred to the boat 217b in the first area 26a by the substrate carrier 131. Then, the front side opening 32 is closed by the gate valve 33, and the load lock chamber 26 is vacuum-exhausted from the exhaust pipe 48, thereby being depressurized.

After the processing, the boat 217a is pulled onto the rotatable table 40 by the boat elevator 115, and the furnace opening is closed by the furnace opening shutter 30. At this time, over the rotatable table 40, the boat 217a supporting the processed wafer 200 and the boat 217b supporting the unprocessed wafer 200 are supported. At this time, the inert gas is supplied from the inert gas suppliers 54a and 54b toward the boats 217a and 217b, respectively. The inert gas supplied toward the boats 217a and 217b is discharged out of the substrate processing apparatus 10 through the exhaust pipe 48.

At this time, since the inert gas is supplied to each of the boats 217a and 217b over the rotatable table 40, heat conduction is suppressed between the second area 26b where the boat 217a supporting the processed wafer 200 is arranged and the first area 26a where the boat 217b supporting the unprocessed wafer 200 is arranged. In other words, it is possible to thermal isolate the boats 217a and 217b from each other by supplying the inert gas from the inert gas suppliers 54a and 54b.

Then, by rotation of the rotatable table 40, the boat 217a supporting the processed wafer 200 is transferred from the second area 26b to the first area 26a, and the boat 217b supporting the unprocessed wafer 200 is transferred from the first area 26a to the second area 26b. At this time, the supply amount of inert gas supplied from each of the inert gas suppliers 54a and 54b to each of the boats 217a and 217b is regulated such that the supply amount of inert gas when transferring the boat 217a supporting the processed wafer 200 from the second area 26b to the first area 26a is greater than the supply amount of inert gas when transferring the boat 217b supporting the unprocessed wafer 200 from the first area 26a to the second area 26b. In other words, the supply amount of inert gas supplied from the inert gas supplier 54a is greater than the supply amount of inert gas supplied from the inert gas supplier 54b. This may reduce the cooling time for the high-temperature boat immediately after the processing, which may improve the speed of substrate processing. Further, by avoiding contact of the processed wafer with the atmosphere, it is possible to prevent the oxidation of films formed during by substrate processing. Further, it is possible to minimize the impact of heat on the unprocessed wafer.

Then, when the boat 217b in the second area 26b supports the unprocessed wafer 200, the inert gas supplier 54a stops the supply of inert gas to the boat 217a supporting the processed wafer 200 in the first area 26a until the boat 217b in the second area 26b is transferred to the process chamber 201. In other words, the supply of inert gas from the inert gas supplier 54a is stopped until the boat 217b in the second area 26b is transferred to the process chamber 201. This may prevent heat from the first area 26a from flowing into the second area 26b. In other words, it is possible to suppress the impact of heat on the unprocessed wafer.

In other words, the positions of the boats 217a and 217b are exchanged by rotating the rotatable table 40 while they are supported on the respective supports 43a and 43b, under a suppressed heat conduction through the supply of inert gas in the respective areas.

Then, the boat 217b is loaded into the process furnace 202 by the boat elevator 115.

After the loading, a predetermined processing is performed on the wafer 200 in the process chamber 201. At this time, if the boat 217a supporting the processed wafer 200 is arranged in the first area 26a and the wafer 200 is cooled, the internal pressure of the load lock chamber 26 is returned to the atmospheric pressure, and then the gate valve 33 is opened. After that, the wafer 200 and the pod 12 are discharged out of the housing 14 in the opposite procedure as described above, and the next wafer 200 is transferred to the boat 217a in the same procedure as described above.

Also in this embodiment, the same effects as in the above-described embodiment may be obtained. Further, in this embodiment, it is possible to further improve the efficiency of cooling by additionally regulating the supply amount of inert gas according to the step.

Although the embodiments of the present disclosure have been specifically described above, the present disclosure is not necessarily limited to the above-described embodiments, and various modifications may be made without departing from the gist of the present disclosure.

For example, in the above-described embodiments, a case where the isolator or the inert gas supplier is used as a heat conduction insulator on the rotatable table 40 has been described as an example, but the present disclosure is not limited to this. In other words, both the isolator 44 and the inert gas suppliers 54a and 54b may be provided on the rotatable table 40. In other words, the boats 217a and 217b may be isolated by the isolator 44, and the inert gas suppliers 54a and 54b may be provided in the respective areas where the isolated boats 217a and 217b are arranged. Also in this embodiment, the same effects as in the above-described embodiments may be obtained. Further, in this embodiment, it is possible to further improve the efficiency of cooling by regulating the supply amount of inert gas according to the step.

Further, in the above-described embodiment, a case where two boats, i.e., the boats 217a and 217b are arranged over the rotatable table 40 has been described as an example, but the present disclosure is not limited to this. In other words, the present disclosure may be similarly applied even when three or more boats are arranged over the rotatable table 40.

Further, in the above-described embodiment, a case where the inert gas supplier for supplying the inert gas to each of a plurality of boats is provided has been described, but the present disclosure is not limited to this. In other words, there may be only one inert gas supplier as long as it suppresses heat conduction between respective boats. For example, an air curtain may be generated between a plurality of boats.

Further, it is desirable to prepare individual recipes used for each processing according to the processing requirements and to store them in the memory 121c via a telecommunication network or the external memory 123. Then, when initiating each processing, it is desirable for the CPU 121a to appropriately select an appropriate recipe from among a plurality of recipes stored in the memory 121c based on the processing requirements. This allows for the reproducible formation of various film types, compositions, qualities, and thicknesses with a single substrate processing apparatus. Further, it is possible to reduce the operator's burden, allowing for avoiding operational errors and rapidly initiating each processing.

Further, the above-described recipe may not be limited to being newly created but, for example, may also be prepared by modifying an existing recipe already installed in the substrate processing apparatus. When updating the recipe, the updated recipe may be installed in the substrate processing apparatus via a telecommunication network or a recording medium containing the recipe. Further, the existing input/output device 122 included in the substrate processing apparatus may be manually operated to directly modify the existing recipe already installed in the substrate processing apparatus.

Further, the above-described embodiments have described an example of forming a film using a batch-type substrate processing apparatus that processes a plurality of substrates at once. The present disclosure is not limited to the above-described embodiments, and for example, may be suitably applied to a single-wafer type substrate processing apparatus that processes one or several substrates one by one. Further, the above-described embodiments have described an example of forming a film using a substrate processing apparatus with a hot-wall-type process furnace. The present disclosure is not limited to the above-described embodiments and may be suitably applied when forming a film using a substrate processing apparatus with a cold-wall-type process furnace as well.

Even when using these substrate processing apparatuses, it is possible to perform each processing using the same processing procedures and processing conditions as described in the above-described embodiments and modifications, resulting in the acquisition of the same effects as in the above-described embodiments and modifications.

Further, the above-described embodiments and other embodiments may be used in appropriate combination. The processing procedures and processing conditions at this time may be the same as the processing procedures and processing conditions in the above-described embodiments and modifications, for example.

According to the present disclosure in some embodiments, it is possible to improve throughput while reducing susceptibility to the effects of heat.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a process chamber in which a substrate is processed;
a plurality of substrate supports configured to support the substrate;
a rotatable table including a plurality of supports configured to support the plurality of substrate supports; and
a heat conduction insulator configured to suppress heat conduction between the plurality of supports.

2. The substrate processing apparatus of claim 1, further comprising a transfer mechanism configured to transfer one substrate support, among the plurality of substrate supports, between the process chamber and the rotatable table.

3. The substrate processing apparatus of claim 1, wherein the process chamber is located above the rotatable table.

4. The substrate processing apparatus of claim 1, wherein the heat conduction insulator is an isolator configured to thermally isolate the plurality of substrate supports from each other.

5. The substrate processing apparatus of claim 4, wherein the isolator is configured to thermally isolate at least an area, on which the substrate is mounted, of the plurality of substrate supports.

6. The substrate processing apparatus of claim 4, wherein the isolator is formed into a plate shape.

7. The substrate processing apparatus of claim 4, wherein the isolator has a structure with a vacuum thermal-insulation effect.

8. The substrate processing apparatus of claim 1, wherein the heat conduction insulator is an inert gas supplier that is provided at the rotatable table and configured to supply an inert gas to each of the plurality of substrate supports.

9. The substrate processing apparatus of claim 8, wherein the inert gas supplier is configured to rotate together with the plurality of substrate supports.

10. The substrate processing apparatus of claim 8, further comprising: above the rotatable table,
a first area where the substrate is transferred to one substrate support of the plurality of substrate supports; and
a second area where another substrate support of the plurality of substrate supports is transferred between the process chamber and the rotatable table.

11. The substrate processing apparatus of claim 10, wherein a supply amount of the inert gas supplied to each of the plurality of substrate supports from the inert gas supplier is set such that a supply amount of the inert gas when transferring the another substrate support of the plurality of the substrate supports to the first area from the second area is greater than a supply amount of the inert gas when transferring the one substrate support of the plurality of the substrate supports to the second area from the first area.

12. The substrate processing apparatus of claim 10, wherein, when a substrate support in the second area among the plurality of substrate supports supports an unprocessed substrate, the inert gas supplier is configured to be capable of stopping the supply of the inert gas to a substrate support in the first area until the substrate support in the second area is transferred to the process chamber.

13. A transfer method of a substrate support, comprising: rotating a rotatable table in a state where a plurality of supports included in the rotatable table support a plurality of substrate supports configured to support a substrate while suppressing heat conduction between the plurality of substrate supports.

14. The transfer method of claim 13, wherein a supply amount of the inert gas supplied to each of the plurality of substrate supports from an inert gas supplier provided at the rotatable table is set such that a supply amount of the inert gas when transferring one substrate support of the plurality of substrate supports to a first area where the substrate is transferred to another substrate support of the plurality of substrate supports from a second area where the one substrate support of the plurality of substrate supports is transferred between a process chamber and the rotatable table is greater than a supply amount of the inert gas when transferring the another substrate support of the plurality of substrate supports to the second area from the first area.

15. The transfer method of claim 13, wherein, when a substrate support in a second area where one substrate support of the plurality of substrate supports is transferred between a process chamber and the rotatable table, among the plurality of substrate supports supports an unprocessed substrate, an inert gas supplier provided at the rotatable table stops the supply of the inert gas to a substrate support in a first area where the substrate is transferred to another substrate support of the plurality of the substrate supports until the substrate support in the second area is transferred to the process chamber.

16. A non-transitory computer-readable recording medium storing a program that causes, by a computer, a substrate processing apparatus to perform a process comprising: rotating a rotatable table in a state where a plurality of supports included in the rotatable table support a plurality of substrate supports configured to support a substrate while suppressing heat conduction between the plurality of substrate supports.

17. The recording medium of claim 16, wherein a supply amount of an inert gas supplied to each of the plurality of substrate support from an inert gas supplier provided at the rotatable table is set such that a supply amount of the inert gas when transferring one substrate support of the plurality of substrate supports to a first area where the substrate is transferred to another substrate support of the plurality of substrate supports from a second area where the one substrate support of the plurality of substrate supports is transferred between a process chamber and the rotatable table is greater than a supply amount of the inert gas when transferring the another substrate support of the plurality of substrate supports to the second area from the first area.

18. The recording medium of claim 16, wherein, when a substrate support in a second area where one substrate support of the plurality of substrate supports is transferred between a process chamber and the rotatable table, among the plurality of substrate supports supports an unprocessed substrate, an inert gas supplier provided at the rotatable table stops the supply of the inert gas to a substrate support in a first area where the substrate is transferred to another substrate support of the plurality of the substrate supports until the substrate support in the second area is transferred to the process chamber.

19. A manufacturing method of a semiconductor device, comprising the transfer claim 13.
